(19) United States
(12) Patent Application Publication
(10) Pub. No.: US 2016/0009945 A1
(43) Pub. Date: Jan. 14, 2016

(54) COMPOSITION, CURED ARTICLE, LAMINATE, METHOD FOR MANUFACTURING UNDERLYING FILM, METHOD FOR FORMING PATTERN, PATTERN AND METHOD FOR MANUFACTURING A RESIST FOR SEMICONDUCTOR PROCESS

(71) Applicant: FUJIFILM Corporation, Tokyo (JP)

(72) Inventors: Yuichiro ENOMOTO, Haibara-gun (JP); Hirotaka KITAGAWA, Haibara-gun (JP); Tadashi OOMATSU, Haibara-gun (JP); Yuichiro GOTO, Haibara-gun (JP)

(73) Assignee: FUJIFILM CORPORATION, Tokyo (JP)

(21) Appl. No.: 14/865,949

(22) Filed: Sep. 25, 2015

Related U.S. Application Data
(63) Continuation of application No. PCT/JP2014/058326, filed on Mar. 25, 2014.

(30) Foreign Application Priority Data
Mar. 27, 2013 (JP) 2013-065612

(51) Int. Cl. C09D 133/14; H01L 21/02; C09D 133/08

(52) U.S. Cl. CPC C09D 133/14; C09D 133/08; H01L 21/02345

(57) ABSTRACT

Provided is a composition capable of producing an underlying film which demonstrates a good adhesiveness between a substrate and a layer to be imprinted, showing a good in-plane uniformity of the thickness, and a small defect density. The composition includes a polymerizable compound, a first solvent, and a second solvent, the first solvent having a boiling point at 1 atm of 160° C. or higher, the second solvent having a boiling point at 1 atm of lower than 160° C., and the content of the polymerizable compound in the composition being less than 1% by mass.

### CROSS-REFERENCE TO RELATED APPLICATIONS

This application is a Continuation of PCT International Application No. PCT/JP2014/058326 filed on Mar. 25, 2014, which claims priority under 35 U.S.C §119 (a) to Japanese Patent Application No. 2013-065612 filed on Mar. 27, 2013. Each of the above application(s) is hereby expressly incorporated by reference, in its entirety, into the present application.

### TECHNICAL FIELD

This invention relates to a composition, a cured article obtained by curing the composition, and a laminate. This invention also relates to a method for manufacturing an underlying film, a method for forming a pattern, and a pattern formed by the method for forming a pattern, all using the composition described above. This invention further relates to a method for manufacturing a resist for semiconductor process using the method for forming a pattern.

### DESCRIPTION OF THE RELATED ART

Nanoimprint technology is a development advanced from embossing technology well known in the art of optical disc production, which comprises pressing a mold original with an embossed pattern formed on its surface (this is generally referred to as “mold”, “stamper” or “template”) against a resin to thereby accurately transfer the micropattern onto the resin through mechanical deformation of the resin. In this, when a mold is once prepared, then microstructures such as nanostructures can be repeatedly molded, and therefore, this is economical, and in addition, harmful wastes and discharges from this nanotechnology are reduced. Accordingly these days, this is expected to be applicable to various technical fields.

Two methods of nanoimprint technology have been proposed; one is a thermal nanoimprint method using a thermoplastic resin as the material to be worked (for example, see S. Chou, et al., Appl. Phys. Lett. Vol. 67, 3114 (1995)), and the other is a photonanoimprint method using a photocurable composition (for example, see M. Colbun, et al., Proc. SPIE, Vol. 3676, 379 (1999)). In the thermal nanoimprint method, a mold is pressed against a polymer resin heated up to a temperature not lower than the glass transition temperature thereof, then the resin is cooled and thereafter released from the mold to thereby transfer the microstructure of the mold onto the resin on a substrate. This method is very simple and convenient, and is applicable to a variety of resin materials and glass materials.

On the other hand, imprinting is known as a method of transferring a micro-pattern onto a photo-cured material, by allowing a curable composition to cure under photo-irradiation through a translucent mold or a translucent substrate, and then by separating the mold. The imprinting may be implemented at room temperature, so that it is applicable to the field of precision working typically for forming ultra-fine patterns such as semiconductor integrated circuit. In recent years, new trends in development of nano-casting based on combination of advantages of the both, and reversal imprinting capable of creating a three-dimensional laminated structure have been reported.

Applications listed below have been proposed for the imprinting.

A first application relates to that a geometry (pattern) per se obtained by molding is functionalized so as to be used as a nano-technology component, or a structural member. Examples of which include a variety of micro- or nano-optical component, high-density recording medium, optical film, and structural member of flat panel display.

A second application relates to building-up of a laminated structure by using a mold capable of simultaneously forming a micro-structure and a nano-structure, or by simple alignment between layers, and use of the laminated structure for manufacturing p-TAS (Micro-Total Analysis System) or biochip.

A third application relates to use of the thus-formed pattern as a mask through which a substrate is worked typically by etching. By virtue of precise alignment and a large degree of integration, this technique can replace the conventional lithographic technique in manufacturing of high-density semiconductor integrated circuit, transistors in liquid crystal display device, and magnetic material for composing next-generation hard disk called patterned medium. Approaches for implementing the imprinting in these applications have been becoming more active in recent years.

With progress of activities in the imprinting, there has been emerging a problem of adhesiveness between the substrate and the curable composition for imprints. In the imprinting, the curable composition for imprints is coated over the substrate, and is allowed to cure under photo-irradiation, while being brought into contact on the surface thereof with a mold, and then the mold is separated. In the process of separating the mold, the cured product may sometimes separate from the substrate, and unfortunately adhere to the mold. This is supposedly because the adhesiveness between the substrate and the cured material is smaller than the adhesiveness between the mold and the cured material. As a solution to this problem, there has been discussed an under layer film-forming composition for imprints for enhancing the adhesiveness between the substrate and the cured material (Patent Literature 1, Patent Literature 2). CITATION LIST

### Patent Literature

[Patent Literature 1] Patent Registration No. 5084728 (JP-A-2009-503139)

[Patent Literature 2] Japanese Translation of PCT International Application Publication No. JP-T-2011-508680

### Non Patent Literature

[Non Patent Literature 1] S. Chou et al.: Appl. Phys. Lett. Vol. 67, 3114(1995)

[Non Patent Literature 2] M. Colbun et al,: Proc. SPIE, Vol. 3676, 379 (1999)

### SUMMARY OF THE INVENTION

### Technical Problem

The present inventors investigated into Patent Literatures 1 and 2, and found that the techniques described in these literatures successfully improved the adhesiveness between the substrate and the layer to be imprinted, but the underlying film occasionally suffered from in-plane nonuniformity of the thickness and large defect density. If the underlying film has such nonuniformity or much defects, the layer to be imprinted provided thereon film becomes nonuniform, and more likely to produce defects in the pattern.

It is therefore an object of this invention to solve the problems described above, and to provide a composition capable of producing an underlying film which demonstrates a good adhesiveness between the substrate and the layer to be imprinted, showing a good in-plane uniformity of the thickness, and a small defect density.

### Solution To Problem

After intensive studies under such situation, the present inventors decided to use two species of solvents in the composition, wherein one species has a higher boiling point than the other has. A so-called two stage heating (two stage baking) has been known as a method for forming a film by curing a composition containing a polymerizable compound. This sort of method includes a first heating by which the composition is partially cured, and a second heating by which the composition is further cured. Now in the first heating, since the solvent having the higher boiling point is retained in the composition in the form of layer, the curable functional group in the polymerizable compound will have an enhanced mobility in the solid component. More specifically, while the curing reaction generally proceeds slowly, the polymerizable compound will mutually collide more frequently, by enhancing mobility of the polymerizable compound in the layer-like composition, and will be able to accelerate the curing reaction in the layer-like composition. The film may therefore be prevented from shrinking or from being roughened due to aggregation of the resin. The present inventors found that the resultant underlying film will consequently have an improved in-plane uniformity of thickness and a reduced defect density, to thereby complete this invention.

Specifically, the above problems are solved by the following <1>, preferably <2>to <18>.

<1>A composition comprising a polymerizable compound, a first solvent and a second solvent; the first solvent having a boiling point at 1 atm of 160° C. or higher; the second solvent having a boiling point at 1 atm of lower than 160° C.; and the composition having a content of the polymerizable compound of less than 1% by mass.
<2>The composition of <1>, which has a total solid content of less than 1% by mass.
<3>The composition of <1>or <2>, which has a content of the first solvent of 1 to 50% by mass and a content of the second solvent of 50 to 99% by mass.
<4>The composition of any one of <1>to <3>, which has a difference between the boiling point at 1 atm of the first solvent and the boiling point at 1 atm of the second solvent of 20 to 60° C.
<5>The composition of anyone of <1>to <4>, wherein the polymerizable compound is a (meth)acrylate compound.
<6>A composition comprising a polymerizable compound, a first solvent, and a second solvent, the composition being directed to form a film after coated over a substrate and heated, the boiling point at 1 atm of the first solvent being not lower than the heating temperature, and the content of the first solvent relative to the solvents contained in the composition being 1 to 50% by mass.
<7>The composition of <6>, wherein the boiling point at 1 atm of the second solvent is lower than the heating temperature.
<8>The composition of <6>or <7>, wherein the composition is the composition descried in any one of <1>to <6>.
<9>The composition of any one of <1>to <8>, given as a composition for forming an underlying layer for imprinting process.
<10>A cured article obtained by curing the composition described in any one of <1>to <9>.
<11>A laminate comprising an underlying layer obtained by curing the composition described in any one of <1>to <9>, and a substrate.
<12>A method for manufacturing an underlying film, the method comprising: applying the composition described in any one of <1>to <9>over a substrate; curing a part of the composition by first heating; and heating the composition by a second heating, subsequent to the first heating, at a temperature higher than the boiling point at 1 atm of the first solvent.
<13>A method for forming a pattern, the method comprising: applying the composition described in any one of <1>to <9>over a substrate; curing the composition by heating; implementing, subsequent to the curing, a second heating at a temperature higher than the boiling point at 1 atm of the first solvent; applying, subsequent to the second heating, a photo-curable composition for imprints over the surface of the underlying film; photo-irradiating the photo-curable composition for imprints while holding it between the substrate having the underlying film formed thereon and a mold with a fine pattern, to thereby cure the photo-curable composition for imprints; and, releasing the mold.
<14>A pattern formed by the method for forming a pattern described in <13>.
<15>A method for manufacturing a resist for semiconductor process, comprising the method for forming a pattern described in <13>.

### Advantageous Effects Of Invention

By the invention, it now became possible to provide a composition capable of producing an underlying film which demonstrates a good adhesiveness between the substrate and the layer to be imprinted, showing a good in-plane uniformity of the thickness, and showing a small defect density.

### BRIEF DESCRIPTION OF DRAWINGS

FIG. 1 illustrates an exemplary manufacturing process when the curable composition for imprints is used for working of a substrate by etching.

### DESCRIPTION OF EMBODIMENTS

The contents of the invention are described in detail hereinunder. In this description, the numerical range expressed by the wording “a number to another number” means the range that falls between the former number indicating the lowermost limit of the range and the latter number indicating the uppermost limit thereof.

In this description, “(meth)acrylate” means acrylate and methacrylate; “(meth)acrylic” means acrylic and methacrylic; “(meth)acryloyl” means acryloyl and methacryloyl. In the invention, monomer is differentiated from oligomer and polymer, and the monomer indicates a compound having a weight-average molecular weight of at most 1,000. In this specification, “functional group” means a group relevant to polymerization reaction.

“Imprint” referred to in the invention is meant to indicate pattern transfer in a size of from 1 nm to 10 mm and preferably meant to indicate pattern transfer in a size of from about 10 nm to 100 (nanoimprint).

### <Composition>

The composition of this invention contains the polymerizable compound, the first solvent, and the second solvent, characterized in that the first solvent has a boiling point at 1 atm of 160° C. or higher, the second solvent has a boiling point at 1 atm of lower than 160° C., and the content of the polymerizable compound in the composition is less than 1% by mass.

The composition of this invention contains the polymerizable compound, the first solvent and the second solvent, wherein the composition is directed to form a film after coated over a substrate and heated, the boiling point at 1 atm of the first solvent is not lower than the heating temperature, and the content of the first solvent relative to the solvents contained in the composition is 1 to 50% by mass.

The composition of this invention may be used in a particularly preferable manner when applied over a substrate, partially cured by a first heating, and further cured by a second heating to form a film. The composition of this invention is also usable, after cured, as a cured article. A laminate, which includes an underlying film formed by curing the composition of this invention and a substrate, is preferably used as a substrate with an etching resist.

The heating temperature in the first heating is generally lower than 160° C. Since the boiling point at 1 atm of the first solvent contained in the composition of this invention is not lower than the heating temperature in the first heating, so that the first solvent remains in a layer composed of the composition even after the first heating. Accordingly, the curable functional group of the polymerizable compound may be enhanced in the mobility in the layer, so that the curing reaction in the layer may be accelerated, to thereby ensure an in-plane uniformity of thickness of the layer, and to reduce the defect density. Therefore, the composition of this invention, used for forming the underlying film after coated and then heated over the substrate, may suitably be used as a composition for forming the underlying layer for imprinting process (may simply be referred to as “the composition of this invention”, hereinafter). This, of course, does not exclude that the composition is used for a purpose other than forming the underlying film for imprinting process. For example, the composition is versatile as a composition for forming an under lying film for improving adhesiveness of a layer, which is composed of a curable composition not for imprints, to the substrate.

The individual components contained in the composition of this invention will be explained below.

### <<Polymerizable Compound>>

The composition of this invention contains the polymerizable compound, the content of which is generally less than 1% by mass relative to the composition of this invention. The polymerizable compound used in this invention is not specifically limited, and is widely selectable from known compounds without departing from the spirit of this invention.

The polymerizable compound is monomer, oligomer and/or polymer having a polymerizable group in the molecule, and is preferably polymer.

The polymerizable compound usable in this invention is exemplified by compound having ethylenic unsaturated bond-containing group, compound having epoxy group, and compound having vinyl ether group.

The compound having ethylenic unsaturated bond-containing group is specifically exemplified by methyl (meth)acrylate, ethyl (meth)acrylate, butyl (meth)acrylate, N-vinylpyrrolidinone, 2-acryloyloxyethyl phthalate, 2-acryloyloxy-2-hydroxyethyl phthalate, 2-acryloyloxyethyl hexahydrophthalate, 2-acryloyloxypropyl phthalate, 2-ethyl-2-butylpropanediol acrylate, 2-ethylhexyl (meth)acrylate, 2-ethylhexylcarbitol (meth)acrylate, 2-hydroxybutyl (meth)acrylate, 2-hydroxyethyl (meth)acrylate, 2-hydroxypropyl (meth)acrylate, 4-hydroxybutyl (meth)acrylate, acrylic acid dimer, benzyl (meth)acrylate, 1- or 2-naphthyl (meth)acrylate, butoxyethyl (meth)acrylate, cetyl (meth)acrylate, ethylene oxide (referred to as “EO”, hereinafter)-modified cresol (meth)acrylate, dipropylene glycol (meth)acrylate, ethoxylated phenyl (meth)acrylate, isooctyl (meth)acrylate, cyclohexyl (meth)acrylate, isobornyl (meth)acrylate, dicyclopentanyl (meth)acrylate, dicyclopentanyloxyethyl (meth)acrylate, isomyristyl (meth)acrylate, lauryl (meth)acrylate, methoxydipropylene glycol (meth)acrylate, methoxytripropylene glycol (meth)acrylate, methoxypolyethylene glycol (meth)acrylate, methoxytriethylene glycol (meth)acrylate, neopentyl glycol benzoate (meth)acrylate, nonylphenoxypolyethylene glycol (meth)acrylate, nonylphenoxypolypropylene glycol (meth)acrylate, octyl (meth)acrylate, p-cumylphenoxyethylene glycol (meth)acrylate, epichlorohydrin (referred to as “ECH”, hereinafter)-modified phenoxy acrylate, phenoxyethyl (meth)acrylate, phenoxydiethylene glycol (meth)acrylate, phenoxyhexaethylene glycol (meth)acrylate, phenoxytetraethylene glycol (meth)acrylate, polyethylene glycol (meth)acrylate, polyethylene glycol-polypropylene glycol (meth)acrylate, polypropylene glycol (meth)acrylate, stearyl (meth)acrylate, EO-modified succinate (meth)acrylate, tribromophenyl (meth)acrylate, EO-modified tribromophenyl (meth)acrylate, tridodecyl (meth)acrylate, p-isopropenylphenol, N-vinylpyrrolidone, N-vinylcaprolactam, diethylene glycol monoethyl ether (meth)acrylate, dimethyloldicyclopentane di(meth)acrylate, di(meth)acrylated isocyanurate, 1,3-butylene glycol di(meth)acrylate, 1,4-butanediol di(meth)acrylate, EO-modified 1,6-hexanediol di(meth)acrylate, ECH-modified 1,6-hexanediol di(meth)acrylate, acryloxypolyethylene glycol acrylate, 1,9-nonanediol di(meth)acrylate, EO-modified bisphenol A di(meth)acrylate, PO-modified bisphenol A di(meth)acrylate, modified bisphenol A di(meth)acrylate, EO-modified bisphenol F di(meth)acrylate, ECH-modified hexahydrophthalate diacrylate, hydroxypivalate neopentylglycol di(meth)acrylate, neopentylglycol di(meth)acrylate, EO-modified neopentylglycol diacrylate, propylene oxide (referred to as “PO”, hereinafter)-modified neopentylglycol diacrylate, caprolactone-modified hydroxypivalate neopentyl glycol, stearic acid-modified pentaerythritol di(meth)acrylate, ECH-modified phthalate di(meth)acrylate, poly(ethylene glycol-tetramethylene glycol) di(meth)acrylate, poly(propylene glycol-tetramethylene glycol) di(meth)acrylate, polyester (di)acrylate, polyethylene glycol di(meth)acrylate, polypropylene glycol di(meth)acrylate, ECH-modified propylene glycol di(meth)acrylate, silicone di(meth)acrylate, triethylene glycol di(meth)acrylate, tetraethylene glycol di(meth)acrylate, dimethyloltricyclodecane di(meth)acrylate, neopentyl glycol-modified trimethylol propane di(meth)acrylate, tripropylene glycol di(meth)acrylate, EO-modified tripropylene glycol di(meth)acrylate, triglycerol di(meth)acrylate, dipropylene glycol di(meth)acrylate, divinylethylene urea, divinylpropylene urea, o-, m-, p-xylylene di(meth)acrylate, 1,3-adamantane diacrylate, norbornane dimethanol di(meth)acrylate, tricyclodecane dimethanol di(meth)acrylate, ECH-modified glycerol tri(meth)acrylate, EO-modified glycerol tri(meth)acrylate, PO-modified glycerol tri(meth)acrylate, pentaerythritol triacrylate, EO-modified phosphate triacrylate, trimethylol propane tri(meth)acrylate, caprolactone-modified trimethylol propane tri(meth)acrylate, EO-modified trimethylol propane tri(meth)acrylate, PO-modified trimethylol propane tri(meth)acrylate, tris(acryloxyethyl) isocyanurate, dipentaerythritol hexa(meth)acrylate, caprolactone-modified dipentaerythritol hexa(meth)acrylate, dipentaerythritol hydroxypenta(meth)acrylate, alkyl-modified dipentaerythritol penta(meth)acrylate, dipentaerythritol poly(meth)acrylate, alkyl-modified dipentaerythritol tri(meth)acrylate, ditrimethylol propane tetra(meth)acrylate, pentaerythritol ethoxytetra (meth)acrylate, and pentaerythritol tetra(meth)acrylate.

The compound having epoxy group is exemplified by bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, hydrogenated bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylol propane triglycidyl ether, polyethylene glycol diglycidyl ether, polypropylene glycol diglycidyl ethers; polyglycidyl ethers of polyether polyols obtained by adding one species, or two or more species of alkylene oxides to aliphatic polyhydric alcohol such as ethylene glycol, propylene glycol, or glycerin; diglycidyl esters of aliphatic long-chain dibasic acids; monoglycidyl ethers of aliphatic higher alcohols; monoglycidyl ethers of phenol, cresol, butyl phenol, or polyether alcohols obtained by adding alkylene oxide to them; and glycidyl esters of higher fatty acids.

The compound having vinyl ether group is exemplified by 2-ethylhexyl vinyl ether, butanediol-1,4-divinyl ether, diethylene glycol monovinyl ether, diethylene glycol monovinyl ether, ethylene glycol divinyl ether, triethylene glycol divinyl ether, 1,2-propanediol divinyl ether, 1,3-propanediol divinyl ether, 1,3-butanediol divinyl ether, 1,4-butanediol divinyl ether, tetramethylene glycol divinyl ether, neopentyl glycol divinyl ether, trimethylolpropane trivinyl ether, trimethylolethane trivinyl ether, hexanediol divinyl ether, tetraethylene glycol divinyl ether, pentaerythritol divinyl ether, pentaerythritol trivinyl ether, pentaerythritol tetravinyl ether, sorbitol tetravinyl ether, sorbitol pentavinyl ether, ethylene glycol diethylenevinyl ether, triethylene glycol diethylenevinyl ether, ethylene glycol dipropylenevinyl ether, triethylene glycol diethylenevinyl ether, trimethylol propane triethylenevinyl ether, trimethylol propane diethylenevinyl ether, pentaerythritol diethylenevinyl ether, pentaerythritol triethylenevinyl ether, pentaerythritol tetraethylenevinyl ether, 1,1,1-tris[4-(2-vinyloxyethoxy)phenyl]ethane, and bisphenol A divinyloxyethyl ether.

A preferable example relates to poly(meth)acrylate compound having an ethylenic unsaturated group (P) and a hydrophilic group (4).

The ethylenic unsaturated group (P) is exemplified by (meth)acryloyloxy group, (meth)acryloylamino group, maleimide group, allyl group, and vinyl group.

The hydrophilic group (Q) is exemplified by alcoholic hydroxy group, carboxy group, phenolic hydroxy group, ether group (preferably polyoxyalkylene group), amino group, amido group, imido group, ureido group, urethane group, cyano group, sulfonamido group, lactone group, and cyclocarbonate group. When the hydrophilic group is a urethane group, the urethane group is preferably exists, in the resin, in the form of —O—C(═O)—NH— together with the neighboring oxygen atom.

The poly(meth)acrylate compound (acrylic resin) preferably contains 20 to 100 mol % of a repeating unit having the ethylenic unsaturated group (P). The acrylic resin preferably contains 20 to 100 mol % of a repeating unit having the hydrophilic group (Q).

The ethylenic unsaturated group (P) and the hydrophilic group (Q) maybe contained in the same repeating unit, or may be contained in different repeating units.

The poly(meth)acrylate compound (acrylic resin) may further contain other repeating unit having neither the ethylenic unsaturated group (P) nor the hydrophilic group (Q). The ratio of content of such other repeating unit in the acrylic resin is preferably 50 mol % or less.

The poly(meth)acrylate compound (acrylic resin) preferably contains a repeating unit represented by Formula (I) below and/or a repeating unit represented by Formula (II) below:

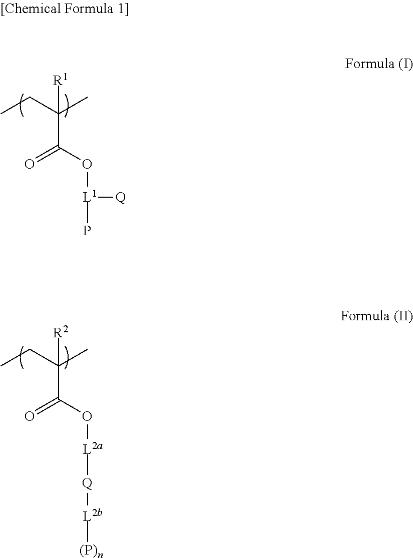

(In Formulae (I) and (II), each of R¹ and R² independently represents a hydrogen atom, methyl group, or hydroxymethyl group, L′ represents a trivalent linking group, L^{2a} represents a single bond or divalent linking group, L^{2b} represents a single bond, divalent linking group or trivalent linking group, P represents an ethylenic unsaturated group, Q represents a hydrophilic group, and n represents 1 or 2.)

Each of R¹ and R² independently represents a hydrogen atom, methyl group or hydroxymethyl group, preferably represents a hydrogen atom or methyl group, and more preferably represents a methyl group.

L¹ represents a trivalent linking group, which is an aliphatic group, alicyclic group, aromatic group or trivalent group configured by combining them, and may contain an ester bond, ether bond, sulfide bond, or nitrogen atom. The trivalent linking group preferably has 1 to 9 carbon atoms.

L^{2a} represents a single bond or divalent linking group. The divalent linking group is an alkylene group, cycloalkylene group, arylene group, or divalent group configured by combining them, and may contain an ester bond, ether bond, or sulfide bond. The divalent linking group preferably has 1 to 8 carbon atoms.

L^{2b} represents a single bond, divalent linking group, or trivalent linking group. The divalent linking groups represented by

L^{2b} are synonymous to those represented by L^{2a}, while defined by the same preferable ranges. The trivalent linking groups represented by

L^{2b} are synonymous to those represented by L¹, while defined by the same preferable ranges.

P represents an ethylenic unsaturated group, which is synonymous to those represented by the ethylenic unsaturated groups exemplified above, while defined by the same preferable ranges of the ethylenic unsaturated groups.

Q represents a hydrophilic group, and is synonymous to those exemplified above, while defined by the same preferable ranges of the hydrophilic groups.

n is 1 or 2, and preferably 1.

Each of L¹, L^{2a} and L^{2b} contains neither ethylenic unsaturated group nor hydrophilic group.

The poly(meth)acrylate compound (acrylic resin) may further contain repeating unit(s) represented by Formula (III) and/or Formula (IV).

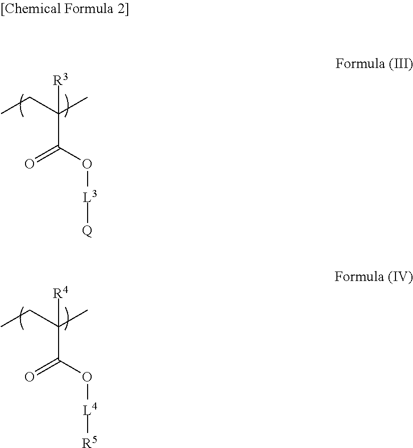

(In Formulae (III) and (IV), each of R³ and R⁴ independently represents a hydrogen atom, methyl group or hydroxymethyl group, each of L³ and L⁴ independently represents a single bond or divalent linking group, Q represents a hydrophilic group, R⁵ represents an aliphatic group having 1 to 12 carbon atoms, alicyclic group having 3 to 12 carbon atoms, or aromatic group having 6 to 12 carbon atoms.)

Each of R³ and R⁴ independently represents a hydrogen atom, methyl group or hydroxymethyl group, preferably represents a hydrogen atom or methyl group, and more preferably represents a methyl group.

Each of L³ and L⁴ independently represents a single bond or divalent linking group. The divalent linking group is synonymous to those represented by L^{2a} in Formula (I), while defined by the same preferable ranges.

Q represents a hydrophilic group, and is synonymous to the hydrophilic groups exemplified above, defined by the same preferable ranges of the hydrophilic group.

R⁵ represents an aliphatic group, alicyclic group, or aromatic group, having 1 to 12 carbon atoms.

The aliphatic group having 1 to 12 carbon atoms is exemplified by alkyl groups having 1 to 12 carbon atoms (for example, methyl group, ethyl group, propyl group, isopropyl group, butyl group, isobutyl group, t-butyl group, pentyl group, isopentyl group, neopentyl group, hexyl group, heptyl group, octyl group, 2-ethylhexyl group, 3,3,5-trimethylhexyl group, isooctyl group, nonyl group, isononyl group, decyl group, isodecyl group, undecyl group, and dodecyl group).

The alicyclic group having 3 to 12 carbon atoms is exemplified by cycloalkyl group having 3 to 12 carbon atoms (for example, cyclopentyl group, cyclohexyl group, norbornyl group, isobornyl group, adamantyl group, and tricyclodecanyl group).

The aromatic group having 6 to 12 carbon atoms is exemplified by phenyl group, naphthyl group, and biphenyl group. Among them, phenyl group and naphthyl group are preferable.

Each of the aliphatic group, the alicyclic group and the aromatic group may have a substituent.

Specific examples of the acrylic resin used in this invention will be enumerated below. In the specific examples below, x denotes 0 to 50 mol %, y denotes 0 to 50 mol %, and z denotes 20 to 100 mol %.

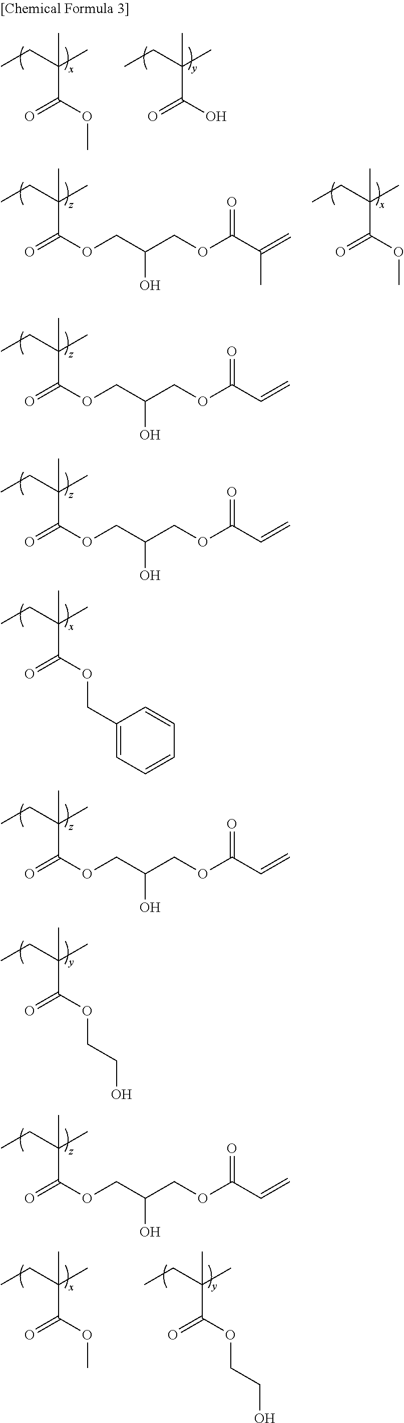

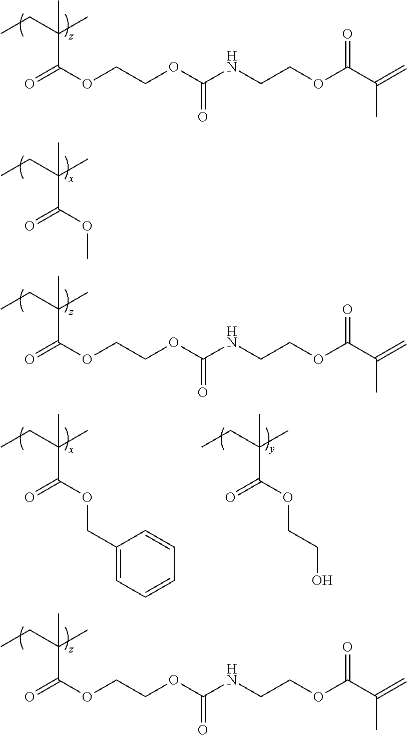

Another example of the polymerizable compound used in this invention may be a polymerizable compound having aromatic rings in the principal chain thereof. This sort of polymerizable compound is exemplified by those whose principal chain is composed of aromatic ring and alkylene group, and more specifically by those whose principal chain is composed of benzene rings and methylene group alternately bound to each other. Also the polymerizable compound preferably has a functional group in the side chain, more preferably has a (meth)acryloyl group in the side chain, and even more preferably has a acryloyl group in the side chain.

The polymerizable compound whose principal chain contains aromatic rings is preferably a polymer mainly composed of a constitutive unit represented by Formula (A) below, and more preferably a polymer in which the constitutive unit represented by Formula (A) above account for 90 mol % or more.

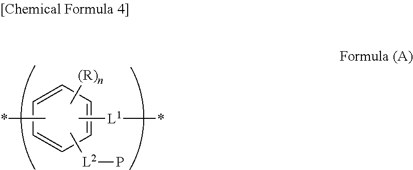

(In Formula (A), R represents an alkyl group, each of L¹ and L² independently represents a divalent linking group, and P represents a polymerizable group. n represents an integer of 0 to 3.)

R preferably represents an alkyl group having 1 to 5 carbon atoms, and more preferably represents a methyl group.

L¹ preferably represents an alkylene group, more preferably represents an alkylene group having 1 to 3 carbon atoms, and even more preferably represents —CH₂—.

L² preferably represents —CH₂—, —O—, —CHR (R represents a substituent)-, or divalent linking group based on combination of two or more of them. R is preferably an OH group.

P preferably represents a (meth)acryloyl group, and more preferably an acryloyl group.

n preferably represents an integer of 0 to 2, and more preferably 0 or 1.

Epoxy poly(meth)acrylate compound is exemplified as another example of the polymerizable compound used in this invention.

The polymerizable compound is exemplified by those described, for example, in paragraph [0040] to [0056] of JP-T2-2009-503139, the contents of which are incorporated into this specification.

Among the polymerizable compounds described above, those having a functional group which is highly adsorptive to the substrate are preferable. The functional group which is highly adsorptive to the substrate is preferably a hydroxy group, carboxy group, amino group, or silane coupling group, among which hydroxy group or carboxy group is particularly preferable.

The polymerizable compound generally has a molecular weight of 1000 or larger, and may be a low molecular compound or polymer, wherein polymer is preferable. The polymerizable compound more preferably has a molecular weight of 3000 or larger, and even more preferably 7500 or larger. The upper limit of the molecular weight of the polymerizable compound is preferably 200000 or smaller, more preferably 100000 or smaller, and even more preferably 50000 or smaller. With such molecular weight, the polymerizable compound may be prevented from volatilizing.

The content of the polymerizable compound used in this invention is less than 1% by mass in the whole ingredients of the composition, preferably less than 0.5% by mass, and more preferably less than 0.2% by mass. The lower limit value is 0.01% by mass or above, although not specifically limited.

The polymerizable compound used in this invention may be a single species, or a mixture of two or more species.

### <<First Solvent>>

The first solvent used in this invention characteristically has a boiling point at 1 atm of 160° C. or higher, and/or has a boiling point at 1 atm not lower than the first heating temperature. The boiling point at 1 atm of the first solvent is 160° C. or higher, preferably 165° C. or higher, and more preferably 170° C. or higher. The upper limit is 250° C., although not specifically limited.

The first solvent will suffice if it has a boiling point at 1 atm of 160° C. or higher, and if it can dissolve therein the composition of this invention. Preferable examples include ethyl 3-ethoxypropionate (b.p. 170° C.), diethylene glycol methyl ethyl ether (b.p. 176° C.), propylene glycol monomethyl ether propionate (b.p. 160° C.), dipropylene glycol methyl ether acetate (b.p. 213° C.), 3-methoxy butyl ether acetate (b.p. 171° C.), diethylene glycol diethyl ether (b.p. 189° C.), diethylene glycol dimethyl ether (b.p. 162° C.), propylene glycol diacetate (b.p. 190° C.), diethylene glycol monoethyl ether acetate (b.p. 220° C.), dipropylene glycol dimethyl ether (b.p. 175° C.), 1,3-butylene glycol diacetate (b.p. 232° C.), and butyl lactate (b.p. 185° C.). Among them, ethylene glycol mono n-butyl ether, and butyl lactate are preferable.

The first solvent used here may be a single species, or a mixture of two or more species.

The content of the first solvent in this invention is 1 to 50% by mass relative to the composition of this invention, more preferably 2 to 40% by mass, even more preferably 3 to 30% by mass, and yet more preferably 5 to 20% by mass.

With the content of the first solvent controlled to 1% by mass or more, a sufficient amount of the first solvent will remain even after the first heating, and thereby the film is more effectively improved in the in-plane uniformity of the thickness and in the defect density. Meanwhile, with the content of the first solvent controlled to 50% by mass or less, the composition of this invention will be less likely to cause vaporization of the solvent during spin coating, and thereby the film will be effectively suppressed from being thinned in the central portion of the substrate as compared with the peripheral portion (nonuniformity of thickness in the radial direction).

### <<Second Solvent>>

The second solvent used in this invention characteristically has a boiling point at 1 atm of lower than 160° C., and/or lower than the heating temperature in the first heating, that is, lower than the boiling point at 1 atm of the first solvent. The boiling point at 1 atm of the second solvent is generally lower than 160° C., preferably 155° C. or below, and more preferably 150° C. or below. The lower limit is generally is 80° C. or above, although not specifically limited.

The difference between the boiling point at 1 atm of the first solvent and the boiling point at 1 atm of the second solvent is preferably 20 to 60° C., more preferably 25 to 55° C., and even more preferably 30 to 50° C. By controlling the difference of the boiling points to 20° C. or larger, the film will retain a sufficient amount of the first solvent after the first heating, and will be improved in the in-plane uniformity of thickness and defect density, meanwhile by controlling the difference to 60° C. or smaller, the composition of this invention will be less likely to cause vaporization of the solvent during spin coating, and thereby the film will be effectively suppressed from being thinned in the central portion of the substrate as compared with the peripheral portion (nonuniformity of thickness in the radial direction).

The second solvent is arbitrarily selectable from solvents capable of dissolving the composition of this invention, and is preferably exemplified by propylene glycol monomethyl ether acetate (b.p. 146° C.), propylene glycol monoethyl ether acetate (b.p. 158° C.), propylene glycol methyl-n-butyl ether (b.p. 155° C.), propylene glycol methyl-n-propyl ether (b.p. 131° C.), propylene glycol monomethyl ether (b.p. 120° C.), and anisole (b.p. 154° C.). Among them, propylene glycol monomethyl ether acetate, and propylene glycol monomethyl ether are preferable.

Only a single species of the second solvent may be used, or two or more species thereof may be used in a mixed manner.

The content of the second solvent in this invention is 50 to 99% by mass relative to the composition of this invention, preferably 60 to 98% by mass, more preferably 70 to 97% by mass, and even more preferably 80 to 95% by mass.

The ratio of contents of the first solvent and the second solvent is preferably (1 to 50):(99 to 50) in terms of ratio by mass (first solvent:second solvent), more preferably (2 to 40):(98 to 60), even more preferably (2 to 40):(98 to 60), and yet more preferably (5 to 20):(95 to 80).

With the ratio by mass controlled in the above described ranges, the in-plane uniformity of the thickness and the defect density may be improved.

### <<Other Ingredient>>

The composition of this invention may contain crosslinking agent, acid or acid generator, polymerization inhibitor, or surfactant, as other ingredient. The amount of addition of these ingredients is preferably 50% by mass or less, relative to the whole ingredients of the composition excluding the solvents (first solvent and second solvent), more preferably 30% by mass or less, and even more preferably 10% by mass or less, wherein it is particularly preferable that the composition contains substantially none of them. The phrase of “contains substantially none of them” now means that the composition contains only reaction agents, catalyst, additives such as polymerization inhibitor, which were used for synthesizing the polymerizable compound, and impurities attributable to reaction byproducts, but contains nothing intentionally added. More specifically, a content of 5% by mass or less is acceptable.

In particular, it is preferable in this invention that the composition contains substantially no low molecular component (having a molecular weight of smaller than 1000, for example) other than the solvent. With such configuration, the low molecular component may be suppressed from subliming during baking, and thereby the effect of this invention may be demonstrated in a more efficient manner.

### Crosslinking Agent

The crosslinking agent is preferably selectable from cation-polymerizable compounds such as epoxy compound, oxetane compound, methylol compound, methylol ether compound, and vinyl ether compound.

Examples of the epoxy compound include Epolite from Kyoeisha Chemical Co. Ltd.; Denacol EX from Nagase chemteX Corporation; EOCN, EPPN, NC, BREN, GAN, GOT, AK and RE Series from Nippon Kayaku Co. Ltd.; Epicoat from Japan Epoxy Resins Co. Ltd.; Epiclon from DIC Corporation; and Tepic Series from Nissan Chemical Industries, Ltd. Two or more species of them may be used in combination.

The oxetane compound is exemplified by Eternacoll OXBP, OXTP and OXIPA from Ube Industries Ltd.; and ARON oxetane OXT-121 and OXT-221 from Toagosei Co. Ltd.

The vinyl ether compound is exemplified by Vectomer Series from Allied Signal, Inc.

The methylol compound and methylol ether compound are exemplified by urea resin, glycouril resin, melamine resin, guanamine resin, and phenol resin. Specific examples include Nikalac MX-270, MX-280, MX-290, MW-390 and BX-4000 from Sanwa Chemical Co. Ltd; and Cymel 301, 303ULF, 350 and 1123 from Cytec Industries Inc.

### Acid or Acid Generator

When the crosslinking agent is contained, an acid, or thermal or photo-acid generator is preferably used. The acid usable for the under layer film-forming composition of the present invention is exemplified by p-toluenesulfonic acid and perfluorobutanesulfonic acid. The thermal acid generator is exemplified by isopropyl p-toluenesulfonate, cyclohexyl p-toluenesulfonate, and SI Series which is an aromatic sulfonate compound from Sanshin Chemical Industry Co. Ltd.

The photo-acid generator used in the present invention is exemplified by sulfonium salt compound, iodonium salt compound, and oxim sulfonate compound. Specific examples include PI2074 from Rhodia Inc.; IRGACURE 250 from BASF; and IRGACURE PAG103, 108, 121 and 203 from BASF.

### Polymerization Inhibitor

The under layer film-forming composition of the present invention preferably contains a polymerization inhibitor, from the viewpoint of shelf stability. Examples of the polymerization inhibitor usable in the present invention include hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-tert-butylphenol), N-nitrosophenylhydroxyamine cerium (I) salt, phenothiazine, pheoxazine, 4-methoxynaphthol, 2,2,6,6-tetramethylpiperidine-l-oxyl, free radical, 2,2,6,6-tetramethylpiperidine, 4-hydroxy-2,2,6,6-tetramethylpiperidine-l-oxyl, free radical, nitrobenzene, and dimethylaniline. Among them, phenothiazine, 4-methoxynaphthol, 2,2,6,6-tetramethylpiperidine-l-oxyl, free radical, 2,2,6,6-tetramethylpiperidine, and 4-hydroxy-2,2,6,6-tetramethylpiperidine-l-oxyl, free radical are preferable, since they exhibit effects even under an anaerobic condition.

### Surfactant

The under layer film-forming composition for imprints of the present invention may contain a surfactant. The surfactant is preferably a nonionic surfactant, and is preferably any of fluorine-containing, Si-based, and fluorine-containing/Si-based ones. The expression of “fluorine-containing/Si-based” means that the surfactant has features of both of fluorine-containing and Si-based surfactants. By using this sort of surfactant, uniformity of coating may be improved, and a good coated film may be obtained by coating using a spin coater or slit scan coater.

The nonionic surfactant usable in the present invention is exemplified by various series under the trade names of Fluorad (from Sumitomo 3M Ltd.), Megafac (from DIC Corporation), Surflon (from AGC Seimi Chemical Co. Ltd.), Unidyne (from Daikin Industries Ltd.), Ftergent (from NEOS Co. Ltd.), Eftop (from Mitsubishi Material Electronic Chemicals Co. Ltd.), Polyflow (from Kyoeisha Chemical Co. Ltd.), KP (from Shin-Etsu Chemical Co. Ltd.), Troysol (from Troy Chemical Industries), PolyFox (From OMNOVA Solutions Inc.), and Capstone (from DuPont).

The under layer film-forming composition of the present invention may be prepared by mixing the individual components described above. After mixing of the individual components, the mixture is preferably filtered through a filter with a pore size of 0.003 μm to 5.0 μm. The filtration may be conducted in a multi-step manner or may be repeated plural times. Filter media usable for the filtration include polyethylene resin, polypropylene resin, fluorine-containing resin and nylon resin, but not limited thereto.

The composition of this invention preferably has a total solid contents in the composition of less than 1% by mass, more preferably 0.01% by mass or more and less than 1% by mass, and even more preferably 0.1% by mass or more and less than 1% by mass.

With the total solid contents controlled less than 1% by mass, the effect of this invention may be demonstrated in a more efficient manner.

### <Curable Composition For Imprints>

The curable composition for imprints used together with the under layer film-forming composition of the present invention generally contains a polymerizable compound and a polymerization initiator.

### Polymerizable Compound

Species of the polymerizable compound used for the curable composition for imprints used in the present invention is not specifically limited without departing from the spirit of the present invention, and is exemplified by polymerizable unsaturated monomer having 1 to 6 groups containing an ethylenic unsaturated linking groups; epoxy compound; oxetane compound; vinyl ether compound; styrene derivative; and propenyl ether and butenyl ether. The curable composition for imprints preferably has a polymerizable group which is polymerizable with the polymerizable group contained in the under layer film-forming composition of the present invention. Among them, (meth)acrylate is preferable. Specific examples of them are exemplified by those described in paragraphs [0020] to [0098] of JP-A-2011-231308, the contents of which are incorporated by reference into this patent specification.

The polymerizable compound preferably contains a polymerizable compound having an alicyclic hydrocarbon group and/or aromatic group, and more preferably contains a polymerizable compound having an alicyclic hydrocarbon group and/or aromatic group, and a polymerizable compound having a silicon atom and/or fluorine atom. Of the whole polymerizable components contained in the curable composition for imprints of the present invention, the total content of the polymerizable compounds having an alicyclic hydrocarbon group and/or aromatic group preferably accounts for 30 to 100% by mass of the total polymerizable compounds, more preferably 50 to 100% by mass, and furthermore preferably 70 to 100% by mass.

In a further preferable embodiment, a (meth)acrylate polymerizable compound having an aromatic group, used as the polymerizable compound, preferably accounts for 50 to 100% by mass of the total polymerizable components, more preferably 70 to 100% by mass, and furthermore preferably 90 to 100% by mass.

In a particularly preferable embodiment, a polymerizable compound (1) described below accounts for 0 to 80% by mass (more preferably 20 to 70% by mass) of the total polymerizable components, a polymerizable compound (2) described below accounts for 20 to 100% by mass (more preferably 50 to 100% by mass) of the total polymerizable components, and a polymerizable compound (3) described below accounts for 0 to 10% by mass (more preferably 0.1 to 6% by mass) of the total polymerizable components:

(1) polymerizable compound having an aromatic group (preferably phenyl group or naphthyl group, and more preferably naphthyl group) and a (meth)acrylate group;

(2) polymerizable compound having an aromatic group . (preferably phenyl group or naphthyl group, and more preferably phenyl group), and two (meth)acrylate groups; and (3) polymerizable compound having at least either of a fluorine atom and silicon atom, and a (meth)acrylate group.

In the curable composition for imprints, content of the polymerizable compound having a viscosity at 25° C. of smaller than 5 mPa·s is preferably 50% by mass or less of the total polymerizable compounds, more preferably 30% by mass or less, and furthermore preferably 10% by mass or less. By adjusting the content in the ranges described above, ink-jetting stability may be improved, and thereby defects in transfer-by-imprint may be reduced.

### Polymerization Initiator

The curable composition for imprints used in the present invention contains a photo-polymerization initiator. The photo-polymerization initiator used in the present invention is arbitrarily selectable from those generating an active species capable of polymerizing the above-described polymerizable compounds under photo-irradiation. The photo-polymerization initiator is preferably a radical polymerization initiator or cation polymerization initiator, and more preferably a radical polymerization initiator. In the present invention, two or more species of the photo-polymerization initiator may be used in combination.

The radical photo-polymerization initiator used in the present invention is selectable typically from those commercially available. Those described for example in paragraph [0091] of JP-A-2008-105414 may preferably be used. Among them, acetophenone-based compound, acylphosphine oxide-based compound, and oxim ester-based compound are preferable from the viewpoints of curing sensitivity and absorption characteristics.

In the present invention, “light” includes not only those in the wavelength regions of UV, near-UV, deep-UV, visible light and infrared, and other electromagnetic waves, but also radiation ray. The radiation ray includes microwave, electron beam, EUV and X-ray. Also laser light such as 248 nm excimer laser, 193 nm excimer laser, and 172 nm excimer laser are usable. These sorts of light may be monochromatic light obtained after being passed through an optical filter, or may be composite light composed of a plurality of light components with different wavelengths.

Content of the photo-polymerization initiator used in the present invention is typically 0.01 to 15% by mass of the whole composition but excluding the solvent, preferably 0.1 to 12% by mass, and more preferably 0.2 to 7% by mass. When two or more species of photo-polymerization initiator are used, the total content falls in the above-described ranges.

If the content of the photo-polymerization initiator is 0.01% by mass or more, there will be preferable trends of improvement in sensitivity (fast curability), resolution, line edge roughness, and film strength. On the other hand, if the content of the photo-polymerization initiator is 15% by mass or less, there will be preferable trends of improvement in translucency, coloration and handleability.

### Surfactant

The curable composition for imprints used in the present invention preferably contains a surfactant. The surfactant used in the present invention is exemplified by those used in the under layer film-forming composition as described above. Content of the surfactant used in the present invention is typically 0.001 to 5% by mass of the whole composition, preferably 0.002 to 4% by mass, and furthermore preferably 0.005 to 3% by mass. When two or more species of surfactant are used, the total content falls in the above-described ranges. If the content of the surfactant falls in the range from 0.001 to 5% by mass of the composition, an effect on uniformity of coating will be good, and degradation in mold transfer characteristics due to excessive surfactant will be less likely to occur.

The surfactant is preferably a nonionic surfactant, preferably contains at least one of fluorine-containing surfactant, Si-based surfactant and fluorine-containing/Si-based surfactant, more preferably contains both of the fluorine-containing surfactant and the Si-based surfactant, or, the fluorine-containing/Si-based surfactant, and most preferably contains the fluorine-containing/Si-based surfactant. Note that the fluorine-containing surfactant and the Si-based surfactant are preferably nonionic surfactants.

The “fluorine-containing/Si-based” means that the surfactant has features of both of fluorine-containing and Si-based surfactants.

By using this sort of surfactant, it is now able to solve problems regarding coating failure such as striation or scaly pattern (non-uniform drying of resist) which possibly occur when the curable composition for imprints is coated over a silicon wafer for manufacturing semiconductor device, glass square substrate for manufacturing liquid crystal display device, and substrates having formed thereon various films including chromium film, molybdenum film, molybdenum alloy film, tantalum film, tantalum alloy film, silicon nitride film, amorphous silicon film, tin oxide doped indium oxide (ITO) film, and tin oxide film. In particular, the under layer film-forming composition of the present invention added with the surfactant may largely be improved in the uniformity of coating, and may achieve appropriate coating characteristics in coating using a spin coater or slit scan coater, irrespective of the size of substrate. Examples of the surfactant usable in the present invention may be referred to paragraph [0097] of JP-A-2008-105414, the content of which is incorporated by reference into this patent specification. The surfactant is also commercially available, typically under the trade name of PF-636 (from OMNOVA Solutions Inc.).

### Non-Polymerizable Compound

The curable composition for imprints used in the present invention may contain a non-polymerizable compound which has, at the terminal thereof, at least one hydroxy group or a polyalkylene glycol structure formed by etherifying the hydroxy group, and contains substantially no fluorine atom and silicon atom.

Content of the non-polymerizable compound is preferably 0.1 to 20% by mass of the whole composition excluding the solvent, more preferably 0.2 to 10% by mass, still more preferably 0.5 to 5% by mass, and furthermore preferably 0.5 to 3% by mass.

### Antioxidant

Preferably, the curable composition for imprints used in the invention contains a known antioxidant. The content of the antioxidant to be in the composition is, for example, from 0.01 to 10% by mass of the total amount of the polymerizable monomers constituting the composition, preferably from 0.2 to 5% by mass. When two or more different types of antioxidants are in the composition, the total amount thereof falls within the above range.

The antioxidant is for preventing fading by heat or photoirradiation, and for preventing fading by various gases such as ozone, active hydrogen NOx, SOx (x is an integer), etc. Especially in the invention, the antioxidant added to the composition brings about the advantage that the cured film is prevented from being discolored and the film thickness is prevented from being reduced through decomposition. The antioxidant includes hydrazides, hindered amine-type antioxidants, nitrogen-containing heterocyclic mercapto compounds, thioether-type antioxidants, hindered phenol-type antioxidants, ascorbic acids, zinc sulfate, thiocyanates, thiourea derivatives, saccharides, nitrites, sulfites, thiosulfates, hydroxylamine derivatives, etc. Of those, preferred are hindered phenol-type antioxidants and thioether-type antioxidants from the viewpoint of their effect of preventing cured film discoloration and preventing film thickness reduction.

Commercial products of the antioxidant usable herein include Irganox 1010, 1035, 1076, 1222 (all by BASF GmbH); Antigene P, 3C, FR, Sumilizer S, Sumilizer GA80 (by Sumitomo Chemical); Adekastab A070, A080, A0503 (by Adeka), etc. These may be used either singly or as combined.

### Polymerization Inhibitor

Furthermore, the curable composition for imprints used in the invention preferably comprises a polymerization inhibitor. The content of the polymerization inhibitor is from 0.001 to 1% by mass, more preferably from 0.005 to 0.5% by mass, and even more preferably from 0.008 to 0.05% by mass, relative to all the polymerizable monomers, and the change in the viscosities over time can be inhibited while maintaining a high curing sensitivity by blending the polymerization inhibitor in an appropriate amount. The polymerization inhibitor may be added at the production of the polymerizable monomer or may be added the curable composition for imprints after the production of the polymerizable monomer.

Preferable examples of the polymerization inhibitor usable in the present invention may be referred to the description in paragraph [0125] of JP-A-2012-094821, the content of which is incorporated by reference into this patent specification.

### Solvent

A solvent may be used for the curable composition for imprints used in the invention, in accordance with various needs. In particular, when a pattern having a thickness of at most 500 nm is formed, the composition preferably contains a solvent. Preferably, the solvent has a boiling point at normal pressure of from 80 to 200° C. Regarding the type of the solvent, any solvent capable of dissolving the composition may be used. Preferred are solvents having at least any one of an ester structure, a ketone structure, a hydroxyl group and an ether structure. Concretely, the solvent is preferably one or more selected from propylene glycol monomethyl ether acetate, cyclohexanone, 2-heptanone, gamma-butyrolactone, propylene glycol monomethyl ether, ethyl lactate. Most preferred is a solvent containing propylene glycol monomethyl ether acetate as securing coating uniformity.

The content of the solvent in the composition for imprints used in the present invention may be suitably optimized depending on the viscosity of the constitutive ingredients except the solvent, the coatability of the composition and the intended thickness of the film to be formed. From the viewpoint of the coatability, the solvent content is preferably from 0 to 99% by mass of the composition. When the composition for imprints used in the present invention is applied onto the substrate by inkjet method, it is preferred that the composition does not substantially contain a solvent (for example 3% by mass or less, preferably 1% by mas or less). On the other hand, when a pattern having a film thickness of 500 nm or less is formed by spin-coating method or the like, the content may be 20 to 99% by mass, preferably 40 to 99% by mass, specifically preferably 70 to 98% by mass.

### Polymer Ingredient

The curable composition for imprints used in the invention may contain a poly-functional oligomer having a larger molecular weight than that of the above-mentioned, other poly-functional monomer within a range capable of attaining the object of the invention, for the purpose of further increasing the crosslinking density of the composition. Examples of the photoradical-polymerizable poly-functional oligomer include various acrylate oligomers such as polyester acrylates, urethane acrylates, polyether acrylates, epoxy acrylates. The amount of the oligomer ingredient to be added to the composition may be preferably from 0 to 30% by mass of the composition except the solvent therein, more preferably from 0 to 20% by mass, even more preferably from 0 to 10% by mass, most preferably from 0 to 5% by mass.

The curable composition for imprints for imprints used in the present invention may further contain a polymer component, in view of improving the dry etching resistance, imprint suitability and curability. The polymer component preferably has a polymerizable functional group in the side chain thereof. Weight-average molecular weight of the polymer component is preferably 2,000 to 100,000, and more preferably 5,000 to 50,000, in view of compatibility with the polymerizable monomer. Amount of addition of the polymer component, with respect to portion of the composition excluding the solvent, is preferably 0 to 30% by mass, more preferably 0 to 20% by mass, and most preferably 2% by mass or less. Pattern formability may be improved by adjusting the content of polymer component having a molecular weight of 2,000 or larger, with respect to the portion of the curable composition for imprints of the present invention excluding the solvent. From the viewpoint of pattern formability, as least as possible amount of resin component is preferable, and therefore the curable composition preferably contains no polymer component other than those composing the surfactant or trace amounts of additives.

In addition to the above-mentioned ingredients, the curable composition for imprints used in the invention may contain, if desired, UV absorbent, light stabilizer, antiaging agent, plasticizer, adhesion promoter, thermal polymerization initiator, colorant, elastomer particles, photoacid enhancer, photobase generator, basic compound, flowability promoter, defoaming agent, dispersant, etc.

The curable composition for imprints of the present invention maybe prepared by mixing the individual components described in the above. Mixing and dissolution are generally proceeded in the temperature range from 0 to 100° C.

The curable composition prepared by mixing the individual components is preferably filtered, typically through a filter with a pore size of 0.003 μm to 5.0 μm, and more preferably 0.01 to 1.0 μm. The filtration may be proceeded in a multi-stage manner, or may be repeated a large number of times. The filtrate may be re-filtered. Material for composing a filter used for filtration may be polyethylene resin, polypropylene resin, fluorine-containing resin, nylon resin or the like, but not specifically limited.

In the curable composition for imprints used in the present invention, a mixture of the total components excluding the solvent preferably has a viscosity of 100 mPa·s or smaller, more preferably 1 to 70 mPa·s, furthermore preferably 2 to 50 mPa·s, and most preferably 3 to 30mPa·s.

The curable composition for imprints used in the present invention after manufacturing is bottled in containers such as gallon bottles or coated bottles, and transported or stored. In this case, the inner space of the containers may be replaced with an inert gas such as nitrogen or argon, for the purpose of preventing deterioration. While the curable composition for imprints may be transported or stored at normal temperature, it is also preferable to control the temperature in the range from −20° C. to 0° C. for the purpose of preventing denaturation. Of course, the curable composition for imprints may be shielded from light up to a level of suppressing the reaction from proceeding.

In permanent films (resists for structural members) for use in liquid-crystal displays (LCD) and in resists for use for substrate processing for electronic materials, the resist is preferably prevented from being contaminated as much as possible with metallic or organic ionic impurities in order that the resist does not interfere with the performance of the products. Accordingly, the concentration of the metallic or organic ionic impurities in the curable composition for imprints of the invention is preferably at most 1 ppm, more preferably at most 100 ppb, even more preferably at most 10 ppb.

<Method for forming Film>

The method for manufacturing an underlying film of this invention includes applying the composition of this invention over a substrate; curing the composition by heating; implementing, subsequent to the curing, a second heating at a temperature higher than the boiling point at 1 atm of the first solvent; applying, subsequent to the second heating, a photo-curable composition for imprints over the surface of the underlying film; photo-irradiating the photo-curable composition for imprints while holding it between the substrate having the underlying film formed thereon and a mold with a fine pattern, to thereby cure the photo-curable composition for imprints; and, releasing the mold.

The composition of this invention is applied over the substrate to form the underlying film. Exemplary methods of application over the substrate include dip coating, air knife coating, curtain coating, wire bar coating, gravure coating, extrusion coating, spin coating, slit scanning, and ink jet process, by which a coated film or liquid droplets are formed over the substrate. The method is preferably coating from the viewpoint of uniformity of thickness of the film, and more preferably spin coating. A part of the composition is then cured by heating (first heating). The heating temperature is preferably not higher than the boiling point at 1 atm of the first solvent, and preferably 5° C. or more lower than the boiling point at 1 atm of the first solvent. More specifically, the composition is preferably heated at 80 to 180° C. After the first heating, the composition is cured by second heating at a temperature higher than the boiling point at 1 atm of the first solvent, and the first solvent is allowed to vaporize. The temperature of the second heating for curing is preferably 10° C. or more higher than the boiling point at 1 atm of the first solvent. More specifically, the curing is allowed to proceed under heating at 200° C. to 250° C. (preferably 200° C. to 230° C.). The second heating has an effect of removing the first solvent, and of allowing the heat curing reaction to fully proceed even if the curing by the first heating should remain insufficient. By implementing the second heating at higher temperatures after the first heating (multi-stage baking), the first solvent possibly remains in the film may be removed, and may advantageously be suppressed from being mixed into the curable composition, in the subsequent process (application of a coating liquid for forming the photo-curable composition for imprints, onto the underlying film).

### <Substrate>

Substrate (wafer or support) on which the under layer film-forming composition of the present invention is coated is selectable, depending on a variety of applications, typically from quartz, glass, optical film, ceramic material, evaporated film, magnetic film, reflective film, metal substrate composed of Ni, Cu, Cr or Fe, paper, SOC (Spin On Carbon), SOG (Spin On Glass), polymer substrates composed of polyester film, polycarbonate film or polyimide film, TFT array substrate, electrode substrate of PDP, glass or translucent plastic substrate, electro-conductive substrate composed of ITO or metal, and substrates used in semiconductor process such as insulating substrate, silicon, silicon nitride, polysilicon, silicon oxide or amorphous silicon, without special limitation. In the present invention, an appropriate under layer film may be formed particularly when a substrate having a small surface energy (for example, 40 to 60 mJ/m² or around) is used. Nevertheless, when the substrate is intended to be etched, a substrate used for semiconductor process is preferably used as described later.

A patterned laminate composed of the substrate, the under layer film and the curable composition for imprints of the present invention may be used as an etching resist. The substrate in this case is exemplified by those (silicon wafer) having formed thereon a film of SOC (Spin On Carbon), SOG (Spin On Glass), SiO₂ or silicon nitride.

Multiple etching onto a substrate may be carried out at the same time. A laminate composed of the substrate, the under layer film and the curable composition for imprints of the present invention is less causative of film separation, and is therefore useful, even under environmental changes or stress applied thereto, when used as a permanent film in devices or structures, in an intact form, or in a form obtained after removing any residual film in recessed portions or removing the under layer film.

In the present invention, in particular, a substrate having a polar group on the surface thereof is preferably used. By using the substrate having a polar group on the surface thereof, the adhesiveness with the under layer film-forming composition tends to improve more effectively. The polar group is exemplified by hydroxy group, carboxy group, and silanol group. Silicon substrate and quartz substrate are particularly preferable.

Geometry of the substrate is not specifically limited, and may be in a sheet form or rolled form. The substrate is also selectable from those of translucent and non-translucent types, depending on combination with the mold, as described later.

<Method for forming Pattern>

The method for forming a pattern of this invention characteristically includes applying the composition of this invention over a substrate; curing the composition by heating (first heating); applying a photo-curable composition for imprints over the surface of the underlying film; photo-irradiating the photo-curable composition for imprints while holding it between the substrate having the underlying film formed thereon and a mold with a fine pattern, to thereby cure the photo-curable composition for imprints; and, releasing the mold. While the step of curing the composition for forming an underlying film may be implemented only once (first heating), the method of this invention preferably includes a step of implementing a second heating at a temperature higher than the boiling point at 1 atm of the first solvent, between the step of curing the composition by heating, and the step of applying the photo-curable composition for imprints over the surface of the underlying film. More specifically, it is preferable that a part of the composition for forming an underlying film is cured by the first heating, and the composition for forming an underlying film is further allowed to cure by the second heating. All steps before the step of forming the underlying film are same as those in the method for manufacturing an underlying film described above, while defined by the same preferable ranges.

The under layer film-forming composition of the present invention is preferably 1 to 10 nm thick as applied (for example, thickness of coated film), and more preferably 2 to 7 nm thick. The thickness of the film after cured is preferably 1 to 10 nm, and more preferably 2 to 7 nm.

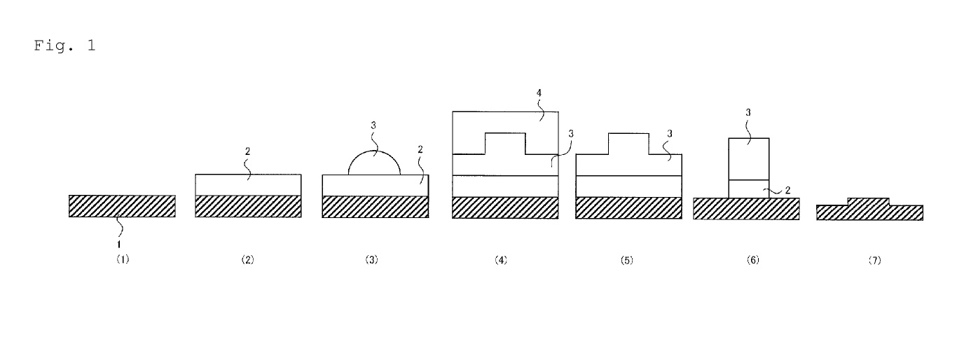

FIG. 1 is a schematic drawing illustrating an exemplary manufacturing process when the curable composition for imprints is used for working of a substrate by etching, wherein reference numeral 1 stands for the substrate, 2 stands for the under layer film, 3 stands for the curable composition for imprints, and 4 stands for the mold. In FIG. 1, the under layer film-forming composition 2 is applied onto the surface of the substrate 1 (2), the curable composition for imprints 3 is applied onto the surface (3), and the mold is applied onto the surface thereof (4). After the photo-irradiation, the mold is separated (5). The laminate is etched according to a pattern formed by the curable composition for imprints (6), the curable composition for imprints 3 and the under layer film-forming composition 2 are separated, to thereby form the substrate with a desired pattern formed thereon (7). The adhesiveness between the substrate 1 and the curable composition for imprints 3 is important, since a poor level of the adhesiveness will fail in exactly transferring the pattern of the mold 4.

More specifically, the method for forming a pattern according to the present invention includes applying the under layer film-forming composition for imprints of the present invention onto the substrate to thereby form the under layer film; and applying the curable composition for imprints onto the under layer film. The method further preferably includes, after applying the under layer film-forming composition for imprints of the present invention onto the substrate, allowing a part of the under layer film-forming composition for imprints to cure through heat or photo-irradiation, and applying thereon the curable composition for imprints. In general, the method includes irradiating light onto the curable composition for imprints and the under layer layer, while holding them between the substrate and a mold with fine patterns to thereby cure the curable composition for imprints, and separating the mold. Details of the method will be described below.

Methods of applying the under layer film-forming composition and the curable composition for imprints of the present invention are respectively selectable from those publicly well known.

The methods of application in the present invention are exemplified by dip coating, air knife coating, curtain coating, wire bar coating, gravure coating, extrusion coating, spin coating, slit scan coating, or inkjet coating, by which a coated film or droplets maybe formed on the substrate or on the under layer film. Thickness of the pattern forming layer composed of the curable composition for imprints of the present invention is 0.03 μm to 30 μm or around, which may vary depending on purpose of use. The curable composition for imprints may be coated by multiple coating. In the method of placing droplets on the under layer film typically by ink jet coating, volume of each droplet is preferably 1 μl to 20 μl. The droplets are preferably arranged on the under layer film while keeping a space in between.

Next, in the patterning method of the invention, a mold is pressed against the surface of the patterning layer for transferring the pattern from the mold onto the patterning layer. Accordingly, the micropattern previously formed on the pressing surface of the mold is transferred onto the patterning layer.

Alternatively, the composition for imprints may be coated over the mold having a pattern formed thereon, and the under layer film may be pressed thereto.

The mold material usable in the invention is described. In the photoimprint lithography with the composition for imprints of the invention, a light-transmissive material is selected for at least one of the mold material and/or the substrate. In the photoimprint lithography applied to the invention, the curable composition for imprints of the invention is applied onto a substrate to form a patterning layer thereon, and a light-transmissive mold is pressed against the surface of the layer, then this is irradiated with light from the back of the mold and the patterning layer is thereby cured. Alternatively, the curable composition for photoimprints is applied onto a light-transmissive substrate, then a mold is pressed against it, and this is irradiated with light from the back of the substrate whereby the curable composition for photoimprints can be cured.

The photoirradiation may be attained while the mold is kept in contact with the layer or after the mold is released. In the invention, preferably, the photoirradiation is attained while the mold is kept in contact with the patterning layer.

The mold usable in the present invention has a pattern to be transferred. The pattern on the mold may be formed with a desired level of processing accuracy, typically by photolithography, electron beam lithography and so forth. Methods of forming the pattern on the mold is not specifically limited in the present invention. Also a pattern formed by the method for forming a pattern according to the present invention may be used as a mold.

Not specifically defined, the light-transmissive mold material for use in the invention may be any one having a desired strength and durability. Concretely, its examples include glass, quartz, light-transparent resin such as PMMA or polycarbonate resin, transparent metal deposition film, flexible film of polydimethylsiloxane or the like, photocured film, metal film, etc.

The non-light-transmissive mold to be used in the invention where a light-transmissive substrate is used is not also specifically defined and may be any one having a predetermined strength. Concretely, examples of the mold material include ceramic material, deposition film, magnetic film, reflective film, metal material of Ni, Cu, Cr, Fe or the like, as well as SiC, silicon, silicon nitride, polysilicon, silicon oxide, amorphous silicon, etc. However, these are not limitative. The shape of the mold is not also specifically defined, and may be any of a tabular mold or a roll mold. The roll mold is used especially when continuous transfer in patterning is desired.

The mold for use in the patterning method of the invention may be processed for surface release treatment for the purpose of enhancing the releasability of the curable composition for imprints from the mold. The mold of the type includes those surface-treated with a silicone-type or fluorine-containing silane coupling agent, for which, for example, commercial release agents such as Daikin's Optool DSX, Sumitomo 3M's Novec EGC-1720 and others are preferred.

In photoimprint lithography with the curable composition for imprints, in general, the mold pressure in the patterning method of the invention is preferably at most 10 atmospheres. When the mold pressure is at most 10 atmospheres, then the mold and the substrate are hardly deformed and the patterning accuracy tends to increase. It is also favorable since the pressure unit maybe small-sized since the pressure to be given to the mold may be low. The mold pressure is preferably selected from the region capable of securing the mold transfer uniformity, within a range within which the residual film of the curable composition for imprints in the area of mold pattern projections may be reduced.

In the patterning method of the invention, the dose of photoirradiation in the step of irradiating the patterning layer with light may be sufficiently larger than the dose necessary for curing. The dose necessary for curing may be suitably determined depending on the degree of consumption of the unsaturated bonds in the curable composition for imprints and on the tackiness of the cured film as previously determined.

In the imprint lithography applied to the present invention, photo-irradiation is conducted while keeping the substrate temperature generally at room temperature, wherein the photo-irradiation may alternatively be conducted under heating for the purpose of enhancing the reactivity. Also photo-irradiation in vacuo is preferable, since a vacuum conditioning prior to the photo-irradiation is effective for preventing entrainment of bubbles, suppressing the reactivity from being reduced due to incorporation of oxygen, and for improving the adhesiveness between the mold and the curable composition for imprints. In the method for forming a pattern according to the present invention, the degree of vacuum in the process of photo-irradiation is preferably in the range from 10⁻¹ Pa to normal pressure.

Light to be used for photoirradiation to cure the curable composition for imprints of the invention is not specifically defined. For example, it includes light and irradiations with a wavelength falling within a range of high-energy ionizing radiation, near-ultraviolet, far-ultraviolet, visible, infrared, etc. The high-energy ionizing radiation source includes, for example, accelerators such as Cockcroft accelerator, Handegraf accelerator, linear accelerator, betatoron, cyclotron, etc. The electron beams accelerated by such an accelerator are used most conveniently and most economically; but also are any other radioisotopes and other radiations from nuclear reactors, such as y rays, X rays, a rays, neutron beams, proton beams, etc. The UV sources include, for example, UV fluorescent lamp, low-pressure mercury lamp, high-pressure mercury lamp, ultra-high-pressure mercury lamp, xenon lamp, carbon arc lamp, solar lamp, etc. The radiations include microwaves, EUV, etc. In addition, laser rays for use in microprocessing of semiconductors, such as LED, semiconductor laser ray, 248 nm KrF excimer laser ray, 193 nm ArF excimer laser ray and others, are also favorably used in the invention. These lights may be monochromatic lights, or may also be lights of different wavelengths (mixed lights).

In photoexposure, the light intensity is preferably within a range of from 1 mW/cm² to 50 mW/cm². When the light intensity is at least 1 mW/cm², then the producibility may increase since the photoexposure time may be reduced; and when the light intensity is at most 50 mW/cm², then it is favorable since the properties of the permanent film formed may be prevented from being degraded owing to side reaction. Also preferably, the dose in photoexposure is within a range of from 5 mJ/cm² to 1000 mJ/cm². When the dose is less than 5 mJ/cm², then the photoexposure margin may be narrow and there may occur problems in that the photocuring may be insufficient and the unreacted matter may adhere to mold. On the other hand, when the dose is more than 1000 mJ/cm², then the composition may decompose and the permanent film formed may be degraded.

Further, in photoexposure, the oxygen concentration in the atmosphere may be controlled to be less than 100 mg/L by introducing an inert gas such as nitrogen or argon into the system for preventing the radical polymerization from being retarded by oxygen.

In the patterning method of the invention, after the pattern layer (a layer comprising the curable composition for imprints layer) is cured through photoirradiation, if desired, the cured pattern may be further cured under heat given thereto. The method may additionally include the post-curing step. Thermal curing of the composition of the invention after photoirradiation is preferably attained at 150 to 280° C., more preferably at 200 to 250° C. The heating time is preferably from 5 to 60 minutes, more preferably from 15 to 45 minutes.

### EXAMPLES

The characteristics of the invention are described more concretely with reference to Production Examples and Examples given below. In the following Examples, the material used, its amount and the ratio, the details of the treatment and the treatment process may be suitably modified or changed not overstepping the scope of the invention. Accordingly, the invention should not be limitatively interpreted by the Examples mentioned below.

### <Formation of Underlying Film>

Each of the polymerizable compounds listed below was diluted by the first solvent and the second solvent summarized in Table below, further added with additives, so as to control the solid content of the polymerizable compound to 0.1% by mass. The mixture was filtered through a 0.1 pm PTFE filter to obtain a composition.

The composition was spin-coated over an SOG (Spin On Glass) film (surface energy=55 mJ/m²) formed on an 8-inch silicon wafer, and heated at the temperature summarized in Table below, on a hot plate for one minute. The composition was further heated for curing at the temperature summarized in Table below, on a hot plate for 5 minutes, to thereby form an underlying film. The cured underlying film was found to be 3 nm thick.

Abbreviations in Table are as follows:
A1: NK Oligo EA-7440/PGMAc (carboxylic acid anhydride-modified epoxy acrylate), from Shin-Nakamura Chemical Co., Ltd.
A2: NK Oligo EA-7120/PGMAc (cresol novolac-type epoxy acrylate), from Shin-Nakamura Chemical Co., Ltd.
A4: NK ester CBX-1N (polyfunctional acrylate monomer), from Shin-Nakamura Chemical Co., Ltd.

### First Solvents

S4: Propylene glycol monomethyl ether propionate, b.p. 160° C.
S5: Ethylene glycol mono-n-butyl ether, b.p. 170° C.
S6: Butyl lactate, b.p. 185° C.
S7: Diethylene glycol monomethyl ether, b.p. 194° C.
S8: y-Butyrolactone, b.p. 204° C.
S9: Propylene carbonate, b.p. 240° C.

### Second Solvents

S1: Propylene glycol monomethyl ether, b.p. 120° C.
S2: Propylene glycol monomethyl ether acetate, b.p. 146° C.

### S3: Anisole, b.p. 154° C.

### Additives

C1: Nikalac MW-100LM (crosslinking agent), from Sanwa Chemical Co., Ltd.
C2: PF-6320 (surfactant), from OMNOVA Solutions, Inc.
C3: V-601 (polymerization initiator), from Wako Pure Chemical Industries, Ltd.

### <<Synthesis of Polymerizable Compound A3>>

Glycidyl methacrylate from Tokyo Chemical Industry, Co., Ltd. was dissolved in PGMEA, to prepare 450 g of a solution having a solid concentration of 15% by mass. To the solution, 1 mol % of polymerization initiator V-601 from Wako Pure Chemical Industries, Ltd. was added, and the mixture was added dropwise to 50 g of PGMEA heated to 100° C., over 6 hours in a nitrogen atmosphere. After the dropwise addition, the reaction liquid was stirred for two hours. After completion of the reaction, the reaction liquid was cooled to room temperature, and poured into 5 L of methanol, and the deposited white powder was collected by filtration, to obtain Compound A3 as a target product.

Compound A3, measured by GPC, was found to have a weight-average molecular weight (standard polystyrene equivalent) of 7200, and a dispersity of 1.5.

### <Preparation of Photo-Curable Composition for Imprints>

The polymerizable compounds, the photo-polymerization initiator, and the additive, summarized in Table below, were mixed, and 200 ppm (0.02% by mass), relative to the monomers, of 4-hydroxy-2,2,6,6-tetramethylpiperidine-1-oxyl, free radical (from Tokyo Chemical Industry Co., Ltd.) was further added as a polymerization inhibitor. The mixture was filtered through a 0.1 μm PTFE filter, to prepare photo-curable composition for imprints V1. In Table below, values are given in ratio by weight.

TABLE 1

| | Availability | V1 |
|---|---|---|
| M-1 | Viscoat #192 (from Osaka Organic Chemical Industry | 48 |
| | Ltd.) | |
| M-3 | Synthesized from α, α′-dichloro-m-xylene and acrylic | 48 |
| | acid | |
| M-4 | R-1620 (from Daikin Industries, Ltd.) | 2 |
| PI-1 | Irgacure 907 (from BASF) | 2 |

[Chemical Formula 5]

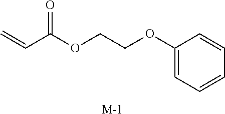

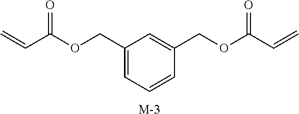

<Difference of Thickness between Center and Periphery (In-Plane Uniformity)>

The underlying film obtained in each Example was observed regarding the thickness at the central portion and peripheral portion (8 cm away from the center) of the wafer, and the difference was denoted by absolute value.

A: <0.1 nm

B: ≦0.1 nm, <0.2 nm

C: ≦0.2 nm, <0.3 nm

D: ≦0.3 nm, <0.4 nm

E: ≦0.4 nm

### <Evaluation Of Defects>

The underlying film obtained in each Example was observed under a scanning electron microscope (S-4800, from Hitachi High-Technologies Corporation) at a 100000× magnification over a 1-μm square region, and sites where the roughened surface is observed was counted.

A: 0 sites, per 1 μm square B: 1 to 2 sites, per 1 μm square C: 3 to 5 sites, per 1 μm square D: 5 to 10 sites, per 1 μm square E: 10 sites or more, per 1 μm square

### <Evaluation of Adhesiveness>

The composition was spin-coated respectively over the surface of SOG film formed on an 8-inch silicon wafer, and, over the surface of a quartz wafer, and heated at the temperature summarized in Table below on a hot plate for one minute. The composition was further heated for curing at the temperature summarized in Table below on the hot plate for 5 minutes, to thereby form underlying films. The cured underlying films were found to be 3 nm thick.

Over the underlying film thus provided over the substrate, the photo-curable composition for imprints V1 conditioned at 25° C. was discharged using an ink jet printer DMP-2831 from FIJIFILM Dimatix Inc., at a droplet volume per nozzle of 1 pl so as to form a square dot matrix with an approximately 100 μm pitch. The quartz wafer was then pressed against the substrate, so as to bring the underlying layer thereof in contact with the pattern forming layer (layer of the photo-curable composition for imprints), and the laminate was photo-irradiated through the quartz wafer using a high pressure mercury lamp at an irradiation dose of 300 mJ/cm². After the exposure, the quartz wafer was separated, and the releasing force was measured. The releasing force now corresponds to the adhesive force F (in N) between the substrate and the photo-curable composition for imprints. The releasing force was measured according to the method described in Comparative Example in paragraphs [0102] to [0107] of JP-A-2011-206977. More specifically, the measurement followed separation steps 1 to 6 and 16 to 18 in FIG. 5 of the publication.

A: F 45

B: 45>F≧40

C: 40>F≧30

D: 30>F≧20

E: 20>F

### <Formation Of Pattern>

The composition for forming an underlying film of Example 1 was spin-coated over an 8-inch silicon wafer, and heated at the temperature summarized in Table below on a hotplate for one minute. The composition was further heated for curing at the temperature summarized in Table below on the hot plate for 5 minutes, to form an underlying film. The cured underlying film was found to be 3 nm thick.

Over the underlying film thus provided over the silicon wafer, the photo-curable composition for imprints V1 conditioned at 25° C. was discharged using an ink jet printer DMP-2831 from FIJIFILM Dimatix Inc., at a droplet volume per nozzle of 1 pl so as to form a square dot matrix with an approximately 100 μm pitch. A mold, having a 40-nm line/space (1/1) pattern with a groove depth of 80 nm, and surface-treated with a silane coupling agent with a perfluoropolyether structure (Optool HD1100, from Daikin Industries, Ltd.), was placed thereon, and while keeping the mold pressed against the composition under a nitrogen gas flow and a pressure of 1 MPa, the laminate was photo-irradiated for curing using a mercury lamp containing a 365 nm component, at a luminous intensity of 10 mW/cm², and an irradiation dose of 200 mJ/cm². After the curing, the mold was slowly separated. The obtained pattern was observed under a scanning electron microscope, and confirmed that a rectangular pattern was obtained.

TABLE 2

| | Polymerizable | | | | | | | | | | | | Evaluation | | | |
|---|---|---|---|---|---|---|---|---|---|---|---|---|---|---|---|---|
| | compound | | First solvent | | Second solvent | | Ratio of | Additive | | Total solid | | | Difference of | | | |
| | | Content | | Content | | Content | contents of | | Content | content in | Heating | Reheating | Thickness between | | | |
| | | (% by | | (% by | | (% by | first solvent and | | (% by | Ccmposition | temperature | temperature | Center and | | | Pattern |
| | Kind | mass) | Kind | mass) | Kind | mass) | second solvent | Kind | mass) | (% by mass) | (Preheating) (° C.) | (° C.) | Periphery | Defect | Adhesivenes | formation |
| Example 1 | A1 | 0.1 | S6 | 9.99 | S2 | 89.91 | 10 | — | — | 0.1 | 180 | 220 | A | A | A | OK |
| Example 2 | A2 | 0.1 | S6 | 9.99 | S2 | 89.91 | 10 | — | — | 0.1 | 180 | 220 | A | B | A | — |
| Example 3 | A3 | 0.1 | S6 | 9.99 | S2 | 89.91 | 10 | — | — | 0.1 | 180 | 220 | A | A | B | — |
| Example 4 | A4 | 0.1 | S6 | 9.99 | S2 | 89.91 | 10 | — | — | 0.1 | 180 | 220 | B | B | A | — |
| Example 5 | A1 | 0.1 | S4 | 9.99 | S2 | 89.91 | 10 | — | — | 0.1 | 180 | 220 | A | B | A | — |
| Example 6 | A1 | 0.1 | S5 | 9.99 | S2 | 89.91 | 10 | — | — | 0.1 | 180 | 220 | A | B | A | — |
| Example 7 | A1 | 0.1 | S7 | 9.99 | S2 | 89.91 | 10 | — | — | 0.1 | 180 | 220 | B | A | A | — |
| Example 8 | A1 | 0.1 | S8 | 9.99 | S2 | 89.91 | 10 | — | — | 0.1 | 180 | 220 | B | A | A | — |
| Example 9 | A1 | 0.1 | S9 | 9.99 | S2 | 89.91 | 10 | — | — | 0.1 | 180 | 220 | C | B | A | — |
| Example 10 | A1 | 0.1 | S6 | 9.99 | S1 | 89.91 | 10 | — | — | 0.1 | 180 | 220 | B | B | A | — |
| Example 11 | A1 | 0.1 | S6 | 9.99 | S3 | 89.91 | 10 | — | — | 0.1 | 180 | 220 | A | A | A | — |
| Example 12 | A1 | 0.1 | S6 | 0.999 | S2 | 98.901 | 1 | — | — | 0.1 | 180 | 220 | A | B | A | — |
| Example 13 | A1 | 0.1 | S6 | 4.995 | S2 | 94.905 | 5 | — | — | 0.1 | 180 | 220 | A | A | A | — |
| Example 14 | A1 | 0.1 | S6 | 29.97 | S2 | 69.93 | 30 | — | — | 0.1 | 180 | 220 | A | A | A | — |
| Example 15 | A1 | 0.1 | S6 | 49.95 | S2 | 49.95 | 50 | — | — | 0.1 | 180 | 220 | A | A | B | — |
| Example 16 | A1 | 0.09 | S6 | 9.99 | S2 | 89.91 | 10 | C1 | 0.01 | 0.1 | 180 | 220 | A | B | A | — |
| Example 17 | A1 | 0.099 | S6 | 9.99 | S2 | 89.91 | 10 | C2 | 0.001 | 0.1 | 180 | 220 | A | B | B | — |
| Example 18 | A1 | 0.099 | S6 | 9.99 | S2 | 89.91 | 10 | C3 | 0.001 | 0.1 | 180 | 220 | A | A | B | — |
| Example 19 | A1 | 0.1 | S6 | 9.99 | S2 | 89.91 | 10 | — | — | 0.1 | 100 | 220 | A | B | A | — |
| Example 20 | A1 | 0.1 | S6 | 9.99 | S2 | 89.91 | 10 | — | — | 0.1 | 150 | 220 | A | B | A | — |
| Example 21 | A1 | 0.1 | S6 | 9.99 | S2 | 89.91 | 10 | — | — | 0.1 | 200 | 220 | A | A | A | — |
| Example 22 | A1 | 0.1 | S6 | 9.99 | S2 | 89.91 | 10 | — | — | 0.1 | 180 | — | A | A | C | — |
| Example 23 | A1 | 0.1 | S6 | 9.99 | S2 | 89.91 | 10 | — | — | 0.1 | 180 | 200 | A | A | A | — |
| Example | A1 | 0.1 | S6 | 9.99 | S2 | 89.91 | 10 | — | — | 0.1 | 180 | 240 | A | A | B | — |
| 24 | | | | | | | | | | | | | | | | |
| Comparative | A1 | 0.1 | — | — | S2 | 99.9 | 0 | — | — | 0.1 | 180 | 220 | A | E | A | — |
| Example 1 | | | | | | | | | | | | | | | | |
| Comparative | A1 | 0.1 | S6 | 0.4995 | S2 | 99.4005 | 0.5 | — | — | 0.1 | 180 | 220 | A | D | A | — |
| Example 2 | | | | | | | | | | | | | | | | |
| Comparative | A1 | 0.1 | S6 | 69.93 | S2 | 29.97 | 70 | — | — | 0.1 | 180 | 220 | C | B | C | — |
| Example 3 | | | | | | | | | | | | | | | | |
| Comparative | A1 | 0.1 | S6 | 89.91 | S2 | 9.99 | 90 | — | — | 0.1 | 180 | 220 | D | C | D | — |
| Example 4 | | | | | | | | | | | | | | | | |
| Comparative | A1 | 0.1 | S6 | 99.9 | — | — | 100 | — | — | 0.1 | 180 | 220 | E | C | E | — |
| Example 5 | | | | | | | | | | | | | | | | |

It was found from Table above that, by using the under layer film-forming composition of the present invention, it became possible to provide the under layer film excellent in the surface roughness and high in the adhesiveness, and to improve the pattern formability by imprint. In contrast, the various characteristics were found to degrade when the under layer film-forming compositions of Comparative Examples were used.

Equivalent results were obtained when, in the individual Examples, the light source used for curing the curable compositions was changed from the high pressure mercury lamp to an LED, metal halide lamp, or excimer lamp.

Also similar trends were confirmed when, in the individual Examples, the substrate used for measuring the adhesiveness was changed from the silicon wafer coated with spin-on-glass (SOG) to a silicon wafer or quartz wafer.

### 1 Substrate

2 Under layer film
3 Curable composition for imprints
4 Mold

1. A composition comprising a polymerizable compound, a first solvent and a second solvent;
the first solvent having a boiling point at 1 atm of 160° C. or higher;
the second solvent having a boiling point at 1 atm of lower than 160° C.; and
the composition having a content of the polymerizable compound of less than 1% by mass.

2. The composition of claim 1, which has a total solid content of less than 1% by mass.

3. The composition of claim 1, which has a content of the first solvent of 1 to 50% by mass and a content of the second solvent of 50 to 99% by mass.

4. The composition of claim 1, which has a difference between the boiling point at 1 atm of the first solvent and the boiling point at 1 atm of the second solvent of 20 to 60° C.

5. The composition of claim 1, wherein the polymerizable compound is a (meth)acrylate compound.

6. A method for manufacturing a film comprising:
coating a composition comprising a polymerizable compound, a first solvent and a second solvent over a substrate, and heating it,
wherein the first solvent has a boiling point at 1 atm of not lower than the heating temperature and the composition have a content of the first solvent of 1 to 50% by mass, relative to solvents contained in the composition.

7. The method for manufacturing a film of claim 6, wherein the second solvent has a boiling point at 1 atm of lower than the heating temperature.

8. The method for manufacturing a film of claim 6, wherein the composition is a composition comprising a polymerizable compound, a first solvent and a second solvent;
the first solvent having a boiling point at 1 atm of 160° C. or higher;
the second solvent having a boiling point at 1 atm of lower than 160° C.; and
the composition having a content of the polymerizable compound of less than 1% by mass.

9. A method for manufacturing an underlying layer for imprinting process, comprising the method for manufacturing a film of claim 6.

10. A cured article obtained by curing the composition described in claim 1.

11. A laminate comprising an underlying layer obtained by curing the composition described in claim 1, and a substrate.

12. A method for manufacturing an underlying film, the method comprising:
applying the composition described in claim 1 over a substrate;
curing a part of the composition by first heating; and
heating the composition by a second heating, subsequent to the first heating, at a temperature higher than the boiling point at 1 atm of the first solvent.

13. A method for forming a pattern, the method comprising:
applying the composition described in claim 1 over a substrate;
curing the composition by heating;
implementing, subsequent to the curing, a second heating at a temperature higher than the boiling point at 1 atm of the first solvent;
applying, subsequent to the second heating, a photo-curable composition for imprints over the surface of the underlying film;
photo-irradiating the photo-curable composition for imprints while holding it between the substrate having the underlying film formed thereon and a mold with a fine pattern, to thereby cure the photo-curable composition for imprints; and,
releasing the mold.

14. A pattern formed by the method for forming a pattern described in claim 13.

15. A method for manufacturing a resist for semiconductor process, comprising the method for forming a pattern described in claim 13.
